(19) United States
(12) Patent Application Publication
(10) Pub. No.: US 2012/0147612 A1
(43) Pub. Date: Jun. 14, 2012

(54) ELECTRONIC DEVICE AND A SUCTION CUP SUITABLE FOR SUCH AN ELECTRONIC DEVICE

(75) Inventors: Mark Johannes Antonius Verhoeven, Deurne (NL); Willem Piet Van Hoof, Horst (NL)

(73) Assignee: KONINKLIJKE PHILIPS ELECTRONICS N.V., EINDHOVEN (NL)

(21) Appl. No.: 13/391,297

(22) PCT Filed: Aug. 19, 2010
(86) PCT No.: PCT/IB10/53740

§ 371 Date: Feb. 20, 2012

(30) Foreign Application Priority Data
Aug. 19, 2009 (EP) 09168126.2

(51) Int. Cl. F21V 21/092; H05K 7/00

(52) U.S. Cl. 362/397; 361/679.01

(57) ABSTRACT

An electronic device (21, 31, 41, 51, 61) comprises at least an electronic element (22, 23) and at least a suction cup (1, 52) for releasably attaching the electronic device (21, 31, 41, 51, 61) to a wall. The suction cup (1, 52) comprises at least a flexible plastic cup (2, 12) and at least one electromagnetic coil, which is electrically connected to the electronic element. The flexible plastic cup (2, 12) and the electromagnetic coil (3, 13) are preferably concentric.

### FIELD OF THE INVENTION

The invention relates to an electronic device comprising at least an electronic element and at least a suction cup for releasably attaching the electronic device to a wall, which suction cup comprises at least a flexible plastic cup.

The invention also relates to a suction cup.

### BACKGROUND OF THE INVENTION

In such an electronic device, which is known from US2005201084A1, the electronic element comprises a light emitting member (LED) and a battery unit which is electrically connected to the LED. The electronic device can be mounted to a wall at any desired location by means of the suction cup. If desired the electronic device can be repositioned by releasing the suction of the suction cup and mounting the suction cup at another location.

A disadvantage of this known electronic device is that since the electronic device has an internal power source it can only be used as long as the battery unit has enough power to energize the LED. Furthermore, the battery unit has a certain volume and weight, which makes the known electronic device relatively bulky.

### SUMMARY OF THE INVENTION

It is an object of the invention to provide an electronic device which overcomes the drawbacks of the known device.

This object is accomplished with the electronic device according to the invention in that the suction cup comprises at least one electromagnetic coil, which is electrically connected to the electronic element.

By means of the electromagnetic coil, wireless power transmission is possible between an electromagnetic coil of an external power source and the electronic device to power the electronic element. The electromagnetic coil of the external power source will be located in a wall to which the suction cup can easily be attached. Since the suction cup comprises the electromagnetic coil, the electromagnetic coil will be positioned relatively close to the wall, so that a relatively good wireless power transmission will be achieved.

Such an external power source is for example known from WO2008012702A1, filed by the current applicant.

An embodiment of the electronic device according to the invention is characterized in that the flexible plastic cup and the electromagnetic coil are concentric.

Due to the concentric orientation it will be easy to align the electromagnetic coil with the electromagnetic coil of the external power source. Furthermore, in this manner, the electromagnetic coil will be positioned automatically parallel to the wall to which the suction cup will be attached.

Another embodiment of the electronic device according to the invention is characterized in that the electromagnetic coil is integrated in the flexible plastic cup.

By integrating the electromagnetic coil in the flexible plastic cup, the electromagnetic coil is protected. Furthermore, the distance between the wall to which the suction cup will be attached and the electromagnetic coil will be relatively small, so that optimal wireless power transmission will be possible.

Yet another embodiment of the electronic device according to the invention is characterized in that the electromagnetic coil is located on the flexible plastic cup, on a side thereof remote from the side to be connected to the wall.

In this manner a standard suction cup can be used and the electromagnetic coil can easily be replaced if needed.

A further embodiment of the electronic device according to the invention is characterized in that the electronic element is integrated in the flexible plastic cup.

By integrating all elements of the electronic device in the flexible plastic cup a very compact electronic device will be obtained which will have the appearance of the suction cup.

Yet a further embodiment of the electronic device according to the invention is characterized in that the electronic element is a lighting element such as a light emitting diode.

The lighting element will be powered by means of the electromagnetic coil which cooperates with the external power source. The lighting element can emit light for as long as desired.

Yet a further embodiment of the electronic device according to the invention is characterized in that the electronic device comprises a housing provided with at least the electronic element, and the suction cup is connected to the housing.

Such a housing may comprise a number of electronic elements being too large to be integrated in the flexible plastic cup of the suction cup. The housing can be attached to the wall by a number of suction cups, with either all suctions cups or only a limited number of the suction cups being provided with an electromagnetic coil. By having more electromagnetic coils the amount of power to be transmitted can be larger.

Another embodiment of the electronic device according to the invention is characterized in that the flexible plastic cup comprises a lip for releasing the suction cup from the wall.

Such a lip will facilitate the removal of the suction cup from the wall to which it is attached.

Yet another embodiment of the electronic device according to the invention is characterized in that the electronic device comprises a rechargeable battery being electrically connected to the electromagnetic coil.

The rechargeable battery can easily be recharged by means of the electromagnetic coil, after which the electronic device can be attached to any desired location.

### BRIEF DESCRIPTION OF THE DRAWINGS

The invention will be explained in more detail with reference to the drawing, in which:

FIG. 1A and 1B are, respectively, a cross sectional view and a top view of a first embodiment of a suction cup according to the invention,

FIG. 2 is a cross sectional view of suction cup as shown in FIG. 1A and 1B and attached to a wall,

FIG. 3A and 3B are cross sections of a second embodiment of a suction cup according to the invention, before being attached to a wall and after being attached to a wall, respectively,

FIG. 4 is a cross section of a first embodiment of an electronic device according to the invention,

FIG. 5 is a cross section of a second embodiment of an electronic device according to the invention,

FIG. 6 is a cross section of a third embodiment of an electronic device according to the invention,

FIG. 7A, 7B and 7C are, respectively, a perspective view, cross sectional view and top view of a fourth embodiment of an electronic device according to the invention,

FIG. 8A and 8B are, respectively, a cross sectional view and a bottom view of a fifth embodiment of an electronic device according to the invention.

### DETAILED DESCRIPTION OF EMBODIMENTS

In the Figures, like parts are indicated by the same reference numerals.

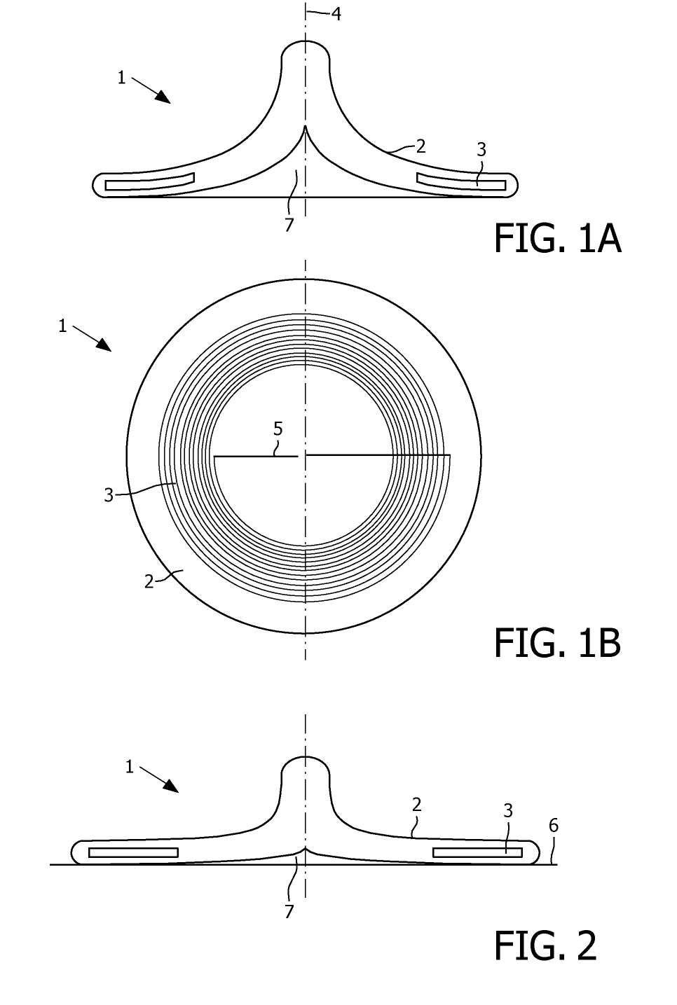

FIGS. 1A and 1B show a first embodiment of a suction cup 1 according to the invention, comprising a flexible plastic cup 2 and an electromagnetic coil 3 being integrated in the flexible plastic cup 2. The electromagnetic coil 3 is concentric with the flexible plastic cup 2 with respect to the axis 4. Connecting wires 5 extend from the electromagnetic coil 3 located inside the flexible plastic cup 2 to outside the flexible plastic cup 2 to be connected to an electronic element. The flexible plastic cup 2 can be made from any plastic known to be suitable for suction cups. The dome-shape of the flexible plastic cup 2 is similar to the shape of well known suction cups. The cup 2 is for example made of silicon.

The electromagnetic coil 3 comprises a number of turns of an electrical wire. The diameter of the electromagnetic coil 3 is such that it fits within the flexible plastic cup 2 and is fully located therein.

FIG. 2 shows the suction cup 1 attached to a wall 6 by means of an underpressure in the space 7 between the flexible plastic cup 2 and the wall 6. In this position, the electromagnetic coil 3 extends parallel to the wall 6 at a relatively close distance from said wall.

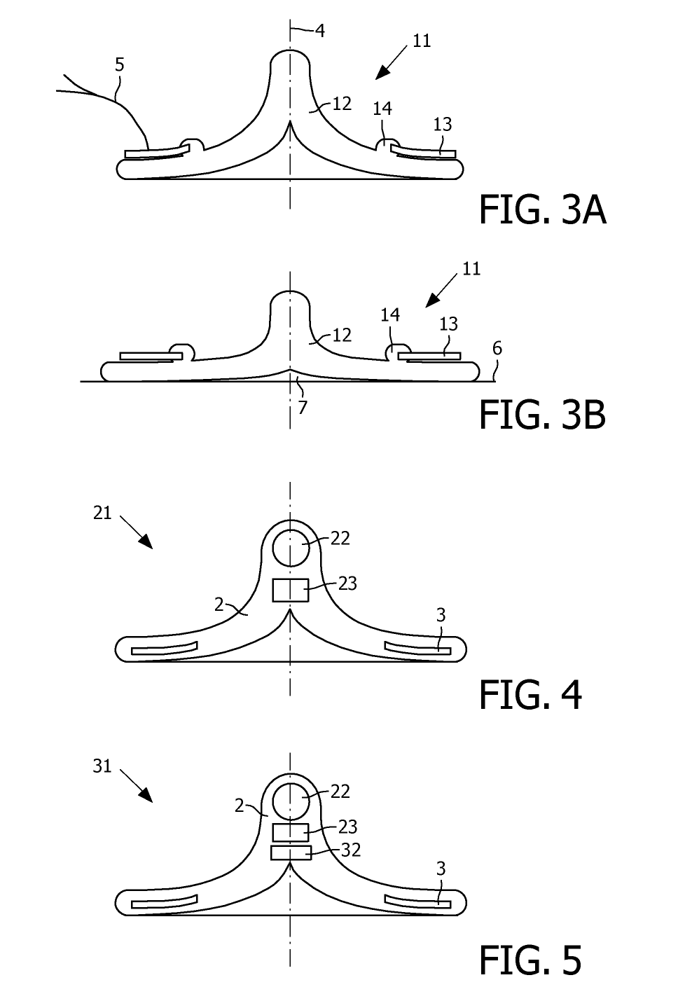

FIGS. 3A and 3B show a second embodiment of a suction cup 11 according to the invention, comprising a flexible plastic cup 12 and an electromagnetic coil 13. The flexible plastic cup 12 is provided with hooks 14 for concentrically holding the electromagnetic coil 13 onto the flexible plastic cup 12. FIG. 3a shows the suction cup 11 in a position where it is released from a wall 6, whilst FIG. 3B shows the suction cup 11 in a position where it is attached to the wall 6. The flexible plastic cup 12 and the electromagnetic coil 13 can be manufactured separately, after which the electromagnetic coil 13 can be connected to the flexible plastic cup 12 by means of the hooks 14.

FIG. 4 shows a first embodiment of an electronic device 21 according to the invention comprising a suction cup with a flexible plastic cup 2. The electronic device 21 further comprises an electromagnetic coil 3, connecting wires 5, a light emitting diode (LED) 22 and driver electronics 23, which are encased by the flexible plastic cup 2. In fact the suction cup itself forms the electronic device 21. The flexible cup 2 must at least be flexible on the side which is attached by suction to the wall 6. The side of the cup 2 which is provided with the electronic elements such as the LED 22 and the driver electronics 23 may also be rigid. The electronic device 21 is suitable to be attached to a wall comprising electromagnetic coils which are powered by means of an external power source. Such a wall is known for example from WO2008012702A1. When the electronic device is attached to such a wall by means of suction, wireless power transmission can take place between the electromagnetic coil in the wall and the electromagnetic coil 3 of the electronic device 21 to power the LED 22. The driver electronics 23 may comprise means to switch the LED 22 on and off, as desired. It is also possible that the LED 22 is switched on and off by switching on and off the power to the external electromagnetic coil in the wall. Since the electronic device 21 is attached to the wall by means of suction, it can easily be removed and attached to the wall opposite another electromagnetic coil of the wall. A suction cup will leave no marks on the wall when it is removed. A requirement to be met by the wall, in addition to having at least one powered electromagnetic coil, is that it must be suitable for a suction cup to be attached thereto. Such requirements, like being smooth enough, are known as such. The wall may extend in any direction, horizontal as well as vertical, and may be slightly curved with a relatively large radius.

FIG. 5 shows a second embodiment of an electronic device 31 according to the invention comprising a suction cup with a flexible plastic cup 2. The electronic device 21 further comprises an electromagnetic coil 3, connecting wires 5, a LED 22, driver electronics 23 and a rechargeable battery 32, which are encased by the flexible plastic cup 2.

When connected to a wall opposite a powered electromagnetic coil in the wall, the LED 22 can be powered and emit light. Simultaneously, the battery 32 may be recharged. When the electronic device 31 is removed from the wall, it can be used at any desired location to emit light, the LED 22 being powered by the battery 32.

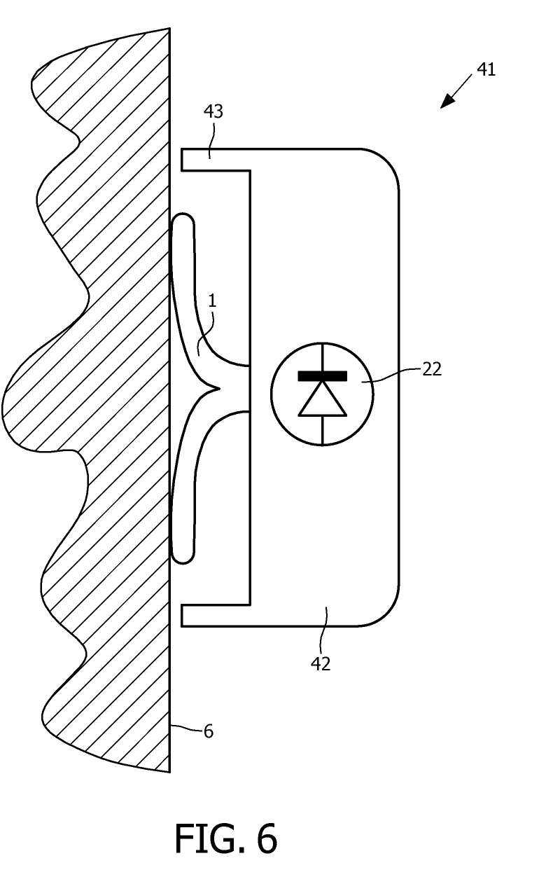

FIG. 6 shows a third embodiment of an electronic device 41 according to the invention comprising a housing 42 and a suction cup 1 as shown in FIGS. 1A and 1B. The housing 42 is provided with a LED 22 and driver electronics. Connecting wires 5 extend from the electromagnetic coil 3 in the flexible plastic cup 2 to the driver electronics located inside the housing 42. Such a housing 42 is larger than the suction cup 1 and can comprise as many electronic elements as desired. Furthermore it can have any desired shape. The housing 42 comprises a cylindrical flange 43 extending along the suction cup 1 so that the suction cup 1 is hidden from view.

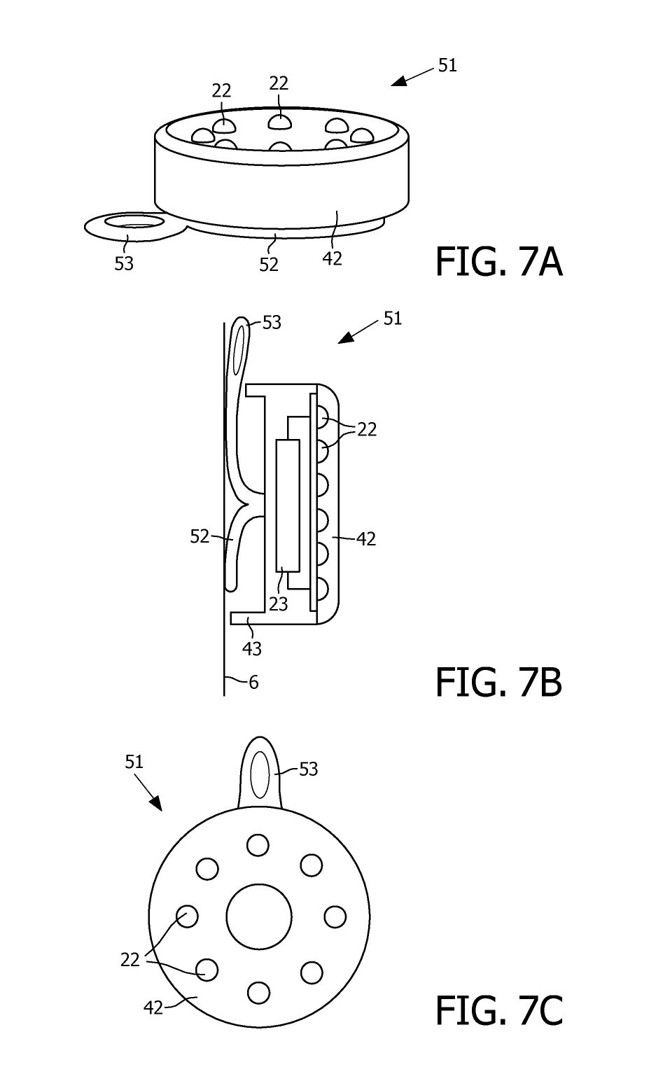

FIGS. 7A, 7B and 7C show a fourth embodiment of an electronic device 51 according to the invention comprising a housing 42 and a suction cup 52 similar to the suction cup 1. The housing 42 is provided with a LED 22 and driver electronics. Connecting wires 5 extend from the electromagnetic coil 3 in the flexible plastic cup 2 to the driver electronics located inside the housing 42. The suction cup 52 differs from the suction cup 1 in that a lip 53 is connected to the flexible plastic cup 2 near an edge thereof. When a person wants to remove the electronic device 51 from a wall to which it is attached by suction, he pulls at the lip 53, thereby causing an edge of the flexible plastic cup 2 to be moved away from the wall and allowing air to enter the space 7. The electronic device 51 can then easily be pulled away from the wall.

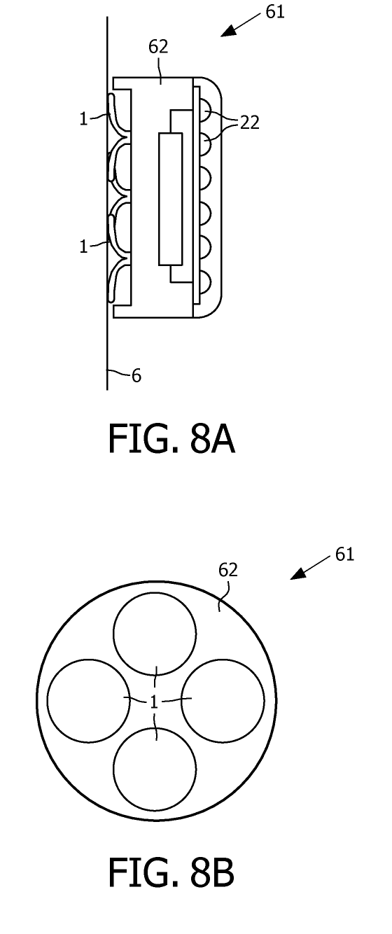

FIG. 8A and 8B show a fifth embodiment of an electronic device 61 according to the invention comprising a housing 62 and four suction cups 1 as shown in FIGS. 1A and 1B. The housing 62 is provided with a number of LEDs 22 and driver electronics. Connecting wires 5 extend from the electromagnetic coil 3 in the flexible plastic cup 2 to the driver electronics located inside the housing 62.

By using four suction cups 1, a heavier electronic device 62 can be safely attached to a wall without the risk that it will become detached from the wall. Furthermore, more power can be transmitted. It is also possible to use only two suction cups 1 and two ordinary suction cups not provided with an electromagnetic coil.

It is also possible to use square electromagnetic coils and square flexible plastic cups or other shapes.

It is also possible to use a relatively large electromagnetic coil which is connected to a number of flexible plastic cups, so that each suction cup comprises a part of the electromagnetic coil.

It is also possible to use a relatively large flexible plastic cup which is provided with a number of electromagnetic coils located in a circle around the axis 4 of the flexible plastic cup.

Instead of a LED 22, the electronic device may comprises any other kind of electronic element which can be powered by means of the electromagnetic coil, like an OLED or a small camera, speaker, sensor, electric fan, radio device, antenna, LCD display etcetera.

1. An electronic device comprising an electronic element and a suction cup for releasably attaching the electronic device to a wall, the suction cup comprising a flexible plastic cup and at least one electromagnetic coil electrically connected to the electronic element, wherein the electromagnetic coil is either located on the flexible plastic cup on a side thereof remote from the side to be connected to the wall or at least partially encased by the flexible plastic cup.

2. An electronic device according to claim 1, wherein the flexible plastic cup and the electromagnetic coil are concentric.

3-4. (canceled)

5. An electronic device according to claim 1, wherein the electronic element is integrated in the flexible plastic cup.

6. An electronic device according to claim 1, wherein the electronic element is a light emitting diode.

7. An electronic device according to claim 1, wherein the electronic device comprises a housing provided with at least the electronic element, and the suction cup is connected to the housing.

8. An electronic device according to claim 1, wherein the flexible plastic cup comprises a lip for releasing the suction cup from the wall.

9. An electronic device according to claim 1, wherein the electronic device comprises a rechargeable battery being electrically connected to the electromagnetic coil.

10. (canceled)
